(19) United States
(12) Patent Application Publication
(10) Pub. No.: US 2013/0113630 A1
(43) Pub. Date: May 9, 2013

(54) TEMPERATURE COMPENSATED FREQUENCY ADJUSTMENT IN A METER READING ENDPOINT

(71) Applicants: Mark K. Cornwall, Spokane, WA (US); Barry Cahill-O'Brien, Spokane, WA (US); Joseph Paolino, Spokane Valley, WA (US)

(72) Inventors: Mark K. Cornwall, Spokane, WA (US); Barry Cahill-O'Brien, Spokane, WA (US); Joseph Paolino, Spokane Valley, WA (US)

(73) Assignee: ITRON, INC., Liberty Lake, WA (US)

(21) Appl. No.: 13/289,327

(22) Filed: Nov. 4, 2011

(51) Int. Cl. H03L 7/08; G08C 15/06

(52) U.S. Cl. 340/870.02; 327/156

(57) ABSTRACT

The presently disclosed subject matter is directed to methods and apparatus enabling production of a stable output from a phase locked loop (PLL) circuit. A crystal controlled oscillator provides a reference signal to the PLL circuit. Temperature variations associated with the crystal cause variations in the operating frequency of the crystal that result in variations of the PLL output frequency. The presently disclosed subject matter compensates for such variations in frequency output by modifying an operation of the PLL circuit based on the temperature variations so that the output frequency remains stable even with temperature induced variations in the reference signal.

### FIELD OF THE SUBJECT MATTER

The presently disclosed subject matter relates to stabilization of operating frequencies in metrology endpoints. More specifically, the presently disclosed subject matter relates to methods and apparatus for providing temperature compensated frequency adjustment in an endpoint.

### BACKGROUND OF THE SUBJECT MATTER

Battery powered Automatic Meter Reading (AMR) devices, often referred to as endpoints, are devices that may be associated with utility consumption measuring devices such as, but not limited to, water, gas, and oil meters. Such endpoints are generally constructed as very low cost devices due, in part, to the need to provide large numbers of such devices to provide utility consumption data from large numbers of consumers. Due to the financial need to maintain manufacturing costs for such devices low, such devices may not be able to be manufactured to provide tight tolerances for many operational aspects thereof without incurring adverse impacts on such manufacturing costs.

### SUMMARY OF THE SUBJECT MATTER

In view of the recognized features encountered in the prior art and addressed by the presently disclosed subject matter, improved methodology and apparatus are disclosed that provides temperature compensated frequency adjustment for automatic meter reading (AMR) devices. Use of the presently disclosed subject matter allows use of low cost components in AMR devices yet maintains operational stability generally achievable only from use of more costly and/or complex configurations.

It is desirable that battery operated endpoints constructed as low cost devices use very little current. In many cases, however, construction techniques used to construct such devices result in the use of crystals to set the radio frequency (RF) of transmitters associated with such devices that may have an excessive temperature drift. In some instances the temperature drift may be in the order of ±20 PPM. In the instance of a system operating at 900 MHz, such draft can translate into a frequency drift of ±18 KHz.

Further, in certain instances, such as operation in industrial, scientific, and medical (ISM) bands, there is a desire to narrow the receive channels to reduce the effects of noise. For example, in the 915 MHz ISM band, if an endpoint transmits with an occupied bandwidth of 90 KHz but has a drift of ±18 KHz, the receive bandwidth must be kept wider than necessary to make sure the endpoint is heard. It is desirable to limit the drift to a relatively much lower amount, such as an amount less than about 4 PPM. It is important, however, to limit drift in any narrowband system regardless of operating frequency.

Crystal controlled oscillators using crystals cut from quartz drift in their frequency of oscillation due to changes in temperature. The amount of change in frequency due to a fixed change in temperature is dependent on the angle of the cut from the quartz. This concept is well understood and curves have been developed showing the relationship as exemplarily illustrated in chart 100 of FIG. 1. As illustrated in FIG. 1, crystal cuts with a negative angle have curves that are closer together than curves with higher positive angle numbers. For example, curves extending from the lower left portion of graph 100 to the upper right portion of the graph corresponding to negative angle crystal cuts exhibit closer spaced characteristic curve lines than other portions of graph 100.

When building a typical temperature compensated crystal oscillator (TXCO), a designer may employ components, typically capacitors, to “pull” the frequency of the crystal as the temperature changes. Crystals typically can be pulled by a small amount, that is, crystal's resonant frequency may be shifted slightly using known techniques. To minimize the amount of pull needed, crystals cut with angles producing flat curves are desired. These would be cuts from +4′ or +5′ angles. Crystal manufacturers can hold a cut angle typically to ±1′ of cut. The problem with this is the difference in tolerance between curves +4′, +5′, and +6′ can be as high as 5 PPM at the temperature extremes (−40° C. to +85° C.). Variations of such amount require the TCXO designer to test each crystal to know how much compensation is needed. This adds cost to the TCXO.

One solution would be to use a TCXO which is commonly available. However, TCXO's are more than three times the cost of a simple crystal and typically draw too much current to be practical for a battery powered endpoint. In light of the issues identified herein with respect to temperature compensation of crystal oscillator, it would be advantageous to provide a temperature compensation arrangement using low-cost crystals while maintaining the frequency stability of the associated transmitter circuitry.

The presently disclosed subject matter relates to a method for providing temperature compensated operation of an endpoint incorporating a phase locked loop (PLL) for producing an output frequency. The method monitors temperature associated with a reference frequency producing component associated with the PLL and then adjusts operation of the PLL to compensate for temperature induced changes in the operating frequency of the reference frequency producing component whereby a predetermined output frequency of the PLL is maintained.

In selected embodiments the method comprises monitoring the temperature of a crystal controlled oscillator. In alternative embodiments, the method comprises monitoring the temperature of a controller associated with the endpoint. In certain embodiments, the crystal has a high temperature versus frequency change curve and in selected such embodiments the crystal has a cut angle of from about -5′ to 0′.

In such methods the method provides adjustment by modifying an operational characteristic of at least one component of the PLL. In particular embodiments, characteristic of a feedback loop of the PLL may be modified.

The presently disclosed subject matter also relates to a temperature compensated endpoint. Such endpoint comprises a controller, a radio frequency (RF) transmitter, a phase locked loop (PLL) circuit configured to establish the transmitter operating frequency, a crystal controlled oscillator configured to couple a reference signal to said PLL and at least one temperature sensor. In such endpoints, the controller is configured to receive temperature related signals from the temperature sensor and to modify operation of said PLL based on the temperature related signals to maintain a predetermined transmitter frequency. In selected embodiments, a memory is associated with the controller. In such embodiments the temperature related signals are related to the temperature of the crystal in the crystal controlled oscillator and the memory is configured to store information relating crystal temperature to changes in operating frequency.

In some embodiments, at least one temperature sensor is positioned proximate the crystal controlled oscillator while in other embodiments, the at least one temperature sensor is positioned proximate the controller. In particular embodiments, the endpoint includes a metrology device configured to measure utility consumption. In such embodiments, the controller is configured to receive utility consumption data from the metrology device and causes the RF transmitter to transmit signals relating to the consumption data. In particular such embodiments, the metrology device is configured to measure one of water, gas, oil, and electricity consumption.

In certain embodiments, a battery operated power supply is provided and configured to supply operating power to the controller, the radio frequency (RF) transmitter, and the phase locked loop (PLL) circuit.

The presently disclosed subject matter also relates to methodologies for maintaining a stable output frequency from a phase locked loop (PLL) circuit. In such embodiments, the method calls for coupling a crystal controlled oscillator as a reference input to a PLL circuit, monitoring a temperature associated with the crystal controlled oscillator, ascertaining expected deviations in the crystal's operating frequency based on the monitored temperature, and modifying operational characteristics of the PLL to maintain a stable output from the PLL based on the expected deviations.

In selected embodiments, the methodology calls for monitoring the temperature of the crystal. In particular embodiments, expected deviations in the crystal's operating frequency may be ascertained by examination of a look up table.

Additional objects and advantages of the presently disclosed subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments and uses of the subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the presently disclosed subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the presently disclosed subject matter, not necessarily expressed in the summarized section, may include and incorporate various combinations of aspects of features, components, or steps referenced in the summarized objects above, and/or other features, components, or steps as otherwise discussed in this application. Those of ordinary skill in the art will better appreciate the features and aspects of such embodiments, and others, upon review of the remainder of the specification.

### BRIEF DESCRIPTION OF THE DRAWINGS

A full and enabling disclosure of the presently disclosed subject matter, including the best mode thereof, directed to one of ordinary skill in the art, is set forth in the specification, which makes reference to the appended figures, in which:

FIG. 1 is a graphical representation corresponding to different temperature response curves for crystal controlled oscillators whose crystals are cut at different angles;

FIG. 2 is a block diagram of an endpoint device incorporating temperature compensation features in accordance with the presently disclosed subject matter; and

FIG. 3 illustrates a block diagram of an exemplary phase locked loop that may be employed with the presently disclosed subject matter.

Repeat use of reference characters throughout the present specification and appended drawings is intended to represent same or analogous features, elements, or steps of the presently disclosed subject matter.

### DETAILED DESCRIPTION OF THE SUBJECT MATTER

As discussed in the Summary section, the presently disclosed subject matter is particularly concerned with providing a temperature compensation arrangement using low-cost crystals while maintaining the frequency stability of the associated transmitter circuitry.

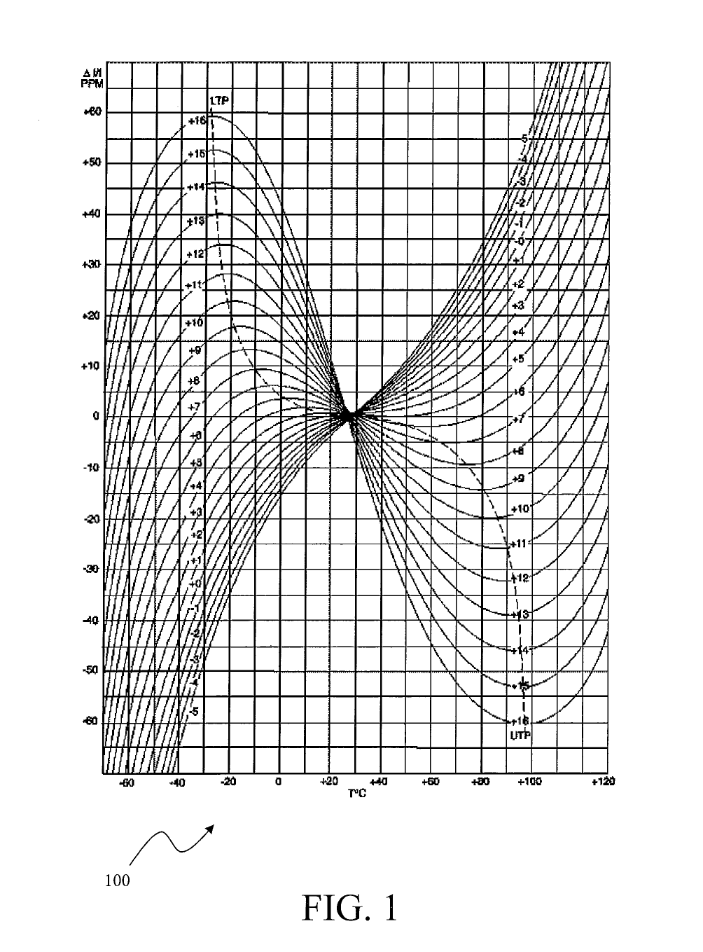

With initial reference to FIG. 1, there is illustrated a graphical representation 100 corresponding to different exemplary temperature response curves for crystal controlled oscillators whose crystals are cut at different angles. As previously noted, graphs similar to graph 100 are generally known and demonstrate the known temperature characteristics of cut quartz crystals as related to the crystal cut angle. In this exemplary graph 100, representative characteristic lines are illustrated indicating crystal cuts ranging from −5′ to +15′ over a temperature range of about −70° C. to about 120° C. Graph 100 also illustrates, by way of vertical scale, a range in parts per million (PPM) expected variations in operating frequency ranging from about −70 to +80 PPM.

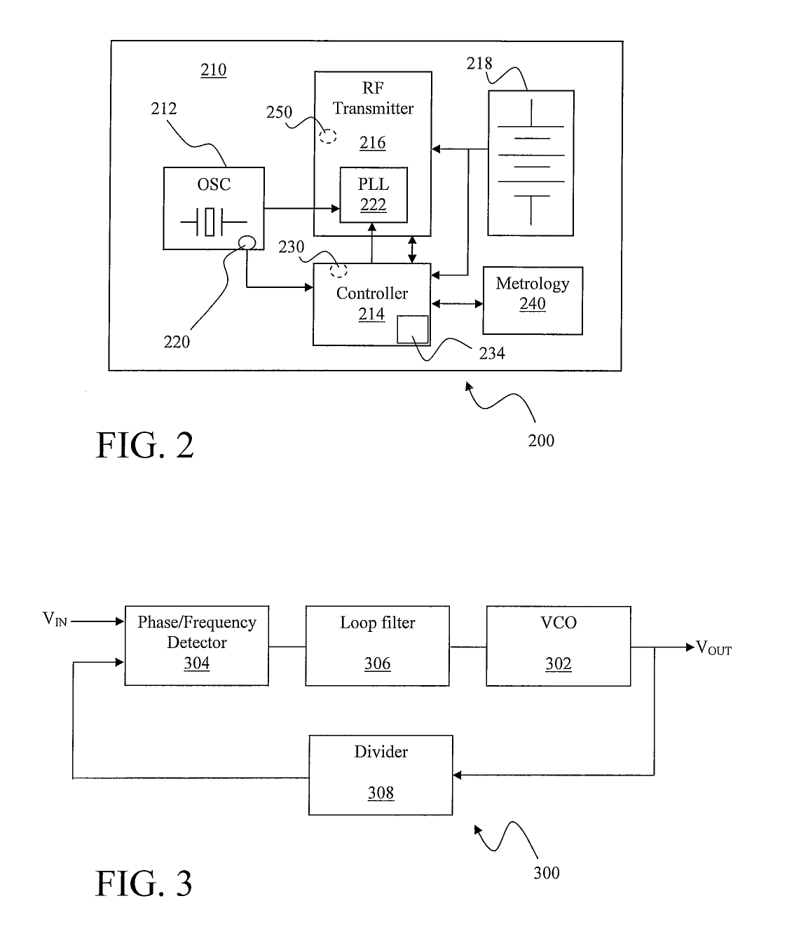

Referring now to FIG. 2, there is illustrated a block diagram 200 of an endpoint device 210 incorporating temperature compensation features in accordance with the presently disclosed subject matter. It should be appreciated that while the presently disclosed subject matter is exemplarily described as being in association with an endpoint device, such is not a specific limitation of the presently disclosed subject matter. More specifically, it should be apparent to those of ordinary skill in the art upon reading of the present disclosure that the presently disclosed subject matter may easily and benifically be applied in any situation where temperature compensation of any device including a PLL is desirable.

Referring still to FIG. 2, endpoint device 210 corresponds, at least in part, to a crystal controlled oscillator 212 that may correspond to a reference oscillator for use in association with a phase locked loop (PLL) 222 portion of an RF transmitter 216. Endpoint device 210 also includes controller 214 which may correspond to a microprocessor, application specific integrated circuit (ASIC), or other device capable of providing necessary controling features such as for endpoint operation.

Controller 214 may also include on board memory 234 for storing operational software as well as collected data from associated metrology devices when involved (not separately illustrated) and other data related to endpoint or metrology device operation. Those of ordinary skill in the art will appreciate that memory 234 may also correspond to (represent) in whole or in part memory devices external to controller 214. All components of endpoint 210 requiring operational power including, for example, controller 214 and RF transmitter 216, may be configured to receive such operating power from battery power supply 218.

PLL 222 is provided to maintain a stable operating frequency for RF transmitter 216. With brief reference to FIG. 3, there is illustrated a block diagram of an exemplary phase locked loop (PLL) 300. As well understood, a phase locked loop (PLL) is a control system that generates an output signal V_{OUT} whose phase is related to the phase of an input or reference signal V_{IN}. In the present instance, such reference signal is provided by oscillator 212. Generally, such PLL circuits include a variable frequency output oscillator 302, exemplarily a voltage controlled oscillator (VCO), and a phase detector 304. These components are configured such that the phase of the reference signal V_{IN} is compared with the phase of the output signal V_{OUT} so as to adjust the frequency of oscillator 302 to keep the phases matched. The signal from the phase detector 304 may be passed through a loop filter 306 to control the oscillator 302 in a feedback loop. In some PLL embodiments, a divider 308 may be included in the feedback loop to permit the oscillator 302 to operate at a higher frequency than the reference signal. In some configurations, the output signal V_{OUT} from oscillator 302 may be multiplied in additional circuitry (not separately illustrated) to produce a higher frequency output signal.

Referring back to FIG. 2, a representative temperature sensor 220 may be associated with crystal controlled oscillator 212 and configured to forward temperature related signals via line 232 to controller 214. In an alternative embodiment of the presently disclosed subject matter, a temperature sensor 230 (represented in dotted lines) associated with controller 214 may be employed to provide temperature related signals to processor 214. In either embodiment, that is, whether a temperature signal is obtained from sensor 220, sensor 230, or other temeprature responsive, sensor, such signal, due in part to the location of the sensor within the operational environment of oscillator 212, may be used by controller 214 in endpoint 210 to measure the temperature and to reprogram the operating frequency in the phase locked loop (PLL) 222. In such manner, the operating frequency of RF transmitter 216 that converts the crystal frequency produced by oscillator 212 to a desired frequency may be temperature compensated to provide a stable desired output frequency.

With brief reference back to FIG. 3, it will be evident to those of ordinary skill in the art that altering any of the components of PLL 300 may be effective to adjust the output frequency of oscillator 302. Thus, for example, in the instance that a divider 308 is provided, changes in the divider ratio may be programmed by controller 214 to effect a change in the output frequency of oscillator 302. Alternatively, per presently disclosed subject matter, an offsetting bias voltage may be applied to a voltge control input of oscillator 302 in the instance that such oscillator is configured as a voltage controlled oscillator (VCO). Other options for modifying opertaion of PLL 300 with an eye toward altering the output frequency will be apparent to or easily derivable by those of ordianry skill in the art. All such techniques for providing modification (adjustment) of the output frequency of PLL 300 are considered a part of the presently disclosed subject matter.

Regardless of the control mechanism employed, an effective methodology has been provided for adjusting the output frequency to compensate for temperature variations and consequent frequency variations of reference oscillator 212. Those skilled in the art will appreciate also that while in exemplary embodiments, the desired output frequency may correspond to a frequency in the 915 MHz ISM band, other ISM bands and other frequecies may be selected as desired or required. Such alternative frequency bands include, but are not limited to, 433 MHz, and 931 MHz.

In alternative embodiments, it is known that the radio frequency integrated circuit (RFIC) used in many endpoints includes a built in temperature sensor, for example, representative sensor 250 (shown in dotted line). In accordance with the presently disclosed subject matter, such sensor 250, as well as sensors 220 and 230, may be used to supply data points for use with a look up table to alter the PLL frequency. In each instance, regardless of the temperature sensor specific location, the temperature signal may be considered at least related to that of the crystal controlled oscillator based, at least in part, on proximity of the sensor due to their proximity within endpoint 210.

In still further alternative embodiments per the presently disclosed subject matter, endpoint devices constructed in accordance with the presently disclosed subject matter may include metrology components such as metrology component 240 illustrated in FIG. 2. Metrology component 240 may correspond to any number of devices whose purpose is to measure consumption of, for example, a utility or a commodity. Such utilities and commodities may include, but are not limited to, water, gas, oil, and electricity. In such exemplary instances, data generated by metrology device 240 would be received and processed by controller 214 for storage and/or transmission via RF transmitter 216 to a remote location. Such remote location may correspond to a central facility (not separately illustrated) for example, for the utility where data collection, billing, and other functionalities may be conducted.

In an exemplary configuration, using a crystal cut at −4′ produces a high, that is, very steep temperature vs. PPM (frequency) change curve. Such curves can easily be compensated for in the controller 214 or RFIC using the presently disclosed subject matter. Since manufacturers can maintain cuts within ±1′, a crystal cut at −4′ might be as low as −5′ or as high as −3′. The difference between such cuts is only around ±2 PPM. Such small error is tolerable and doesn't require testing of each crystal.

Thus, it is evident that use of the presently disclosed subject matter adds TCXO functionality to endpoints with little to no cost added to the endpoint. In certain instances, where existing temperature sensors are already present within endpoint components, the presently disclosed subject matter may be implemented entirely in software with the inclusion of lookup data stored in also already existing on board memory.

While the presently disclosed subject matter has been described in detail with respect to specific embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the presently disclosed subject matter as would be readily apparent to one of ordinary skill in the art.

In accordance with 37 C.F.R. §1.121, a claim listing including the status and text of all claims as currently presented appears below. The present amendments do not add any new matter to the subject application. Claims 1 through 20 are presented, of which claims 1, 8 and 17 are independent claims. LISTING OF CURRENTLY PENDING CLAIMS

1. A method for providing temperature compensated operation of an endpoint incorporating a phase locked loop (PLL) for producing an output frequency, comprising:
monitoring temperature associated with a reference frequency producing component associated with the PLL of the endpoint using a temperature sensor; and
adjusting operation of the PLL to compensate for temperature induced changes in the operating frequency of the reference frequency producing component,
whereby a predetermined output frequency of the PLL is maintained.

2. A method as in claim 1, wherein monitoring comprises monitoring the temperature of a crystal controlled oscillator.

3. A method as in claim 1, wherein monitoring comprises monitoring the temperature of a controller associated with the endpoint.

4. A method as in claim 1, wherein adjusting comprises modifying an operational characteristic of at least one component of the PLL.

5. A method as in claim 4, wherein modifying comprises modifying a characteristic of a feedback loop of the PLL.

6. A method as in claim 1, wherein the reference frequency producing component is a crystal having a high temperature versus frequency change curve.

7. A method as in claim 6, wherein the crystal has a crystal cut angle between about −5′ and 0′.

8. A temperature compensated endpoint, comprising:
a controller;
a radio frequency (RF) transmitter;
a phase locked loop (PLL) circuit configured to establish the transmitter operating frequency;
a crystal controlled oscillator configured to couple a reference signal to said PLL; and
at least one temperature sensor,
wherein said controller is configured to receive temperature related signals from said at least one temperature sensor and to modify operation of said PLL based on said temperature related signals to maintain a predetermined transmitter frequency.

9. An endpoint as in claim 8, further comprising:
a memory associated with said controller,
wherein said temperature related signals are related to the temperature of the crystal in said crystal controlled oscillator and wherein said memory is configured to store information relating crystal temperature to changes in operating frequency.

10. An endpoint as in claim 9, wherein said at least one temperature sensor is positioned proximate said crystal controlled oscillator.

11. An endpoint as in claim 9, wherein said at least one temperature sensor is positioned proximate said controller.

12. An endpoint as in claim 8, further comprising:
a metrology device configured to measure utility consumption,
wherein said controller is configured to receive utility consumption data from said metrology device and to cause said RF transmitter to transmit signals relating to said consumption data.

13. An endpoint as in claim 12, wherein said metrology device is configured to measure one of water, gas, oil, and electricity consumption.

14. An endpoint as in claim 8, further comprising a battery operated power supply configured to supply operating power to said controller, said radio frequency (RF) transmitter, and said phase locked loop (PLL) circuit.

15. An endpoint as in claim 8, wherein the crystal controlled oscillator includes a crystal having a high temperature versus frequency change curve.

16. A method as in claim 15, wherein the crystal has a crystal cut angle between about −5′ and 0′.

17. Methodology for maintaining a stable output frequency from a phase locked loop (PLL) circuit, comprising:
coupling a crystal controlled oscillator as a reference input to a PLL circuit;
monitoring a temperature associated with the crystal controlled oscillator using a temperature sensor;
ascertaining expected deviations in the crystal's operating frequency based on the monitored temperature; and
modifying operational characteristics of the PLL to maintain a stable output from the PLL based on the expected deviations.

18. Methodology as in claim 17, wherein monitoring comprises monitoring the temperature of the crystal.

19. Methodology as in claim 17, wherein ascertaining comprises examining a look up table.

20. Methodology as in claim 17, wherein coupling comprises coupling a crystal having a cut angle between about −5′ and 0′ as a reference input to a PLL circuit.
